(19) United States
(12) Patent Application Publication
(10) Pub. No.: US 2021/0225689 A1
(43) Pub. Date: Jul. 22, 2021

(54) PROXIMITY PIN, SUBSTRATE PROCESSING APPARATUS, AND METHOD OF PROCESSING SUBSTRATE IN SUBSTRATE PROCESSING APPARATUS

(71) Applicants: BOE Technology Group Co., Ltd., Beijing (CN); Hefei Xinsheng Optoelectronics Technology Co., Ltd., Hefei, Anhui (CN)

(72) Inventors: Weishuai Zhang, Beijing (CN); Xinjie Zhang, Beijing (CN); Dawei Yang, Beijing (CN); Hanlin Wang, Beijing (CN); Rong Li, Beijing (CN); Bin Hu, Beijing (CN)

(73) Assignees: BOE Technology Group Co., Ltd., Beijing (CN); Hefei Xinsheng Optoelectronics Technology Co., Ltd., Hefei, Anhui (CN)

(21) Appl. No.: 16/302,772

(22) PCT Filed: Nov. 21, 2017
(86) PCT No.: PCT/CN2017/112089

§ 371 Date: Nov. 19, 2018

(51) Int. Cl. H01L 21/687; H01L 21/68

(52) U.S. Cl. CPC H01L 21/68742; H01L 21/68785; H01L 21/68; H01L 21/6875

(57) ABSTRACT

The present application discloses a proximity pin for supporting a substrate in a substrate processing apparatus. The proximity pin includes a pin head part and a support pad part. The pin head part is configured to support the substrate in the substrate processing apparatus, and includes a first end and a second end opposite to the first end. The first end is configured to be in contact with the substrate placed on the proximity pin. The support pad part is connected to the pin head part at the second end of the pin head part, and has a diameter larger than a maximum diameter of the pin head part.

### TECHNICAL FIELD

The present invention relates to display technology, more particularly, to a proximity pin, a substrate processing apparatus, and a method of processing a substrate in a substrate processing apparatus.

### BACKGROUND

Lithography technique is widely utilized in fabricating semiconductor devices. In a lithography process, a photoresist solution is applied on the surface of a substrate to form a photoresist layer. The photoresist layer is subject to exposure and development to form a desired photoresist pattern. Typically, the photoresist layer formed by applying the photoresist solution on the substrate is first subject to a baking process. During the baking process, the substrate is transferred into a hot plate baking apparatus for baking the substrate.

### SUMMARY

In one aspect, the present invention provides a proximity pin for supporting a substrate in a substrate processing apparatus, comprising a pin head part configured to support the substrate in the substrate processing apparatus, and comprising a first end and a second end opposite to the first end, the first end being configured to be in contact with the substrate placed on the proximity pin; and a support pad part connected to the pin head part at the second end of the pin head part, and has a diameter larger than a maximum diameter of the pin head part.

Optionally, the proximity pin further comprises a threaded pin part configured to threadedly secure the proximity pin to the hot plate in the substrate processing apparatus; and a body part connecting the support pad part and the threaded pin part.

Optionally, the first end of the pin head part has a first diameter smaller than a second diameter of the second end of the pin head part.

Optionally, the pin head part and the support pad part have a combined height greater than approximately 0.4 mm.

Optionally, a ratio of the diameter of the support pad part to a maximum diameter of any other parts of the proximity pin is in a range of approximately 1.1:1.0 to approximately 10:1.0; and a ratio of a maximum diameter of the pin head part to the maximum diameter of any parts of the proximity pin other than the support pad part and the pin head part is in a range of approximately 0.5:1.0 to approximately 1.05:1.0.

In another aspect, the present invention provides a substrate processing apparatus, comprising a hot plate; and at least one of the proximity pin described herein.

Optionally, the first end of the pin head part has a first diameter smaller than a second diameter of the second end of the pin head part.

Optionally, the pin head part and the support pad part have a total height greater than approximately 0.4 mm.

Optionally, the at least one of the proximity pin comprise a first proximity pin; and the hot plate comprises a hole configured to receive the first proximity pin in the hole.

Optionally, the first proximity pin further comprises a threaded pin part and a body part connecting the support pad part and the threaded pin part; the hole in the hot plate is a threaded hole configured to receive the threaded pin part of the first proximity pin; and the first proximity pin is threadedly secured in the hot plate through the threaded pin part.

Optionally, the at least one of the proximity pin comprise a second proximity pin; the second proximity pin is secured on the hot plate through an adhesive tape adhering the support pad part and the hot plate together.

Optionally, the adhesive tape comprises an opening; and the pin head part extends through the opening.

Optionally, the adhesive tape is a high temperature resistant adhesive tape.

Optionally, the at least one of the proximity pin comprise a plurality of first proximity pins and a plurality of second proximity pins; the hot plate comprises a plurality of holes, each of which is configured to receive one of the plurality of first proximity pins; each of the plurality of first proximity pins is secured in one of the plurality of holes in the hot plate; and each of the plurality of second proximity pins is secured on the hot plate through an adhesive tape adhering the support pad part and the hot plate together.

Optionally, the pin head part and the support pad part of each of the plurality of first proximity pins have a first combined height; the pin head part and the support pad part of each of the plurality of second proximity pins have a second combined height; and the first combined height is substantially the same as the second combined height.

Optionally, each of the first combined height and the second combined height is greater than approximately 0.4 mm.

Optionally, each of the plurality of first proximity pins further comprises a threaded pin part and a body part connecting the support pad part and the threaded pin part; each of the plurality of holes is a threaded hole configured to receive the threaded pin part of one of the plurality of first proximity pins; and each of the plurality of first proximity pins is threadedly secured in the hot plate through the threaded pin part.

In another aspect, the present invention provides a method of processing a substrate in a substrate processing apparatus described herein, comprising placing the substrate on at least one of the proximity pin; and baking the substrate in the substrate processing apparatus.

Optionally, the at least one of the proximity pin comprise a plurality of first proximity pins and a plurality of second proximity pins; each of the plurality of first proximity pins comprises the pin head part, the support pad part, a threaded pin part, and a body part connecting the support pad part and the threaded pin part; each of the plurality of first proximity pins is threadedly secured in the hot plate through the threaded pin part; and each of the plurality of second proximity pins comprises the pin head part and the support pad part; and prior to placing the substrate on at least one of the proximity pin, the method further comprising placing the plurality of second proximity pins on the hot plate; and securing each of the plurality of second proximity pins onto the hot plate using an adhesive tape adhering the support pad par and the hot plate together.

Optionally, the method further comprises changing a position of at least one of the plurality of second proximity pins on the hot plate by removing the adhesive tape from the at least one of the plurality of second proximity pins; moving the at least one of the plurality of second proximity pins to a new position on the hot plate; and securing the at least one of the plurality of second proximity pins at the new position using the adhesive tape.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of a conventional substrate processing apparatus.

FIG. 2 is a schematic diagram illustrating the structure of a proximity pin in some embodiments according to the present disclosure.

FIG. 3 is a plan view of the proximity pin in FIG. 2.

FIG. 4 is a schematic diagram illustrating the structure of a proximity pin in some embodiments according to the present disclosure.

FIG. 5 is a schematic diagram illustrating the structure of a proximity pin in some embodiments according to the present disclosure.

FIG. 6 is a schematic diagram illustrating the structure of a proximity pin in some embodiments according to the present disclosure.

FIG. 7 is a schematic diagram illustrating the structure of a substrate processing apparatus in some embodiments according to the present disclosure.

FIG. 8 is a schematic diagram illustrating the structure of a substrate processing apparatus in some embodiments according to the present disclosure.

FIG. 9 is a plan view of the substrate processing apparatus in FIG. 8.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

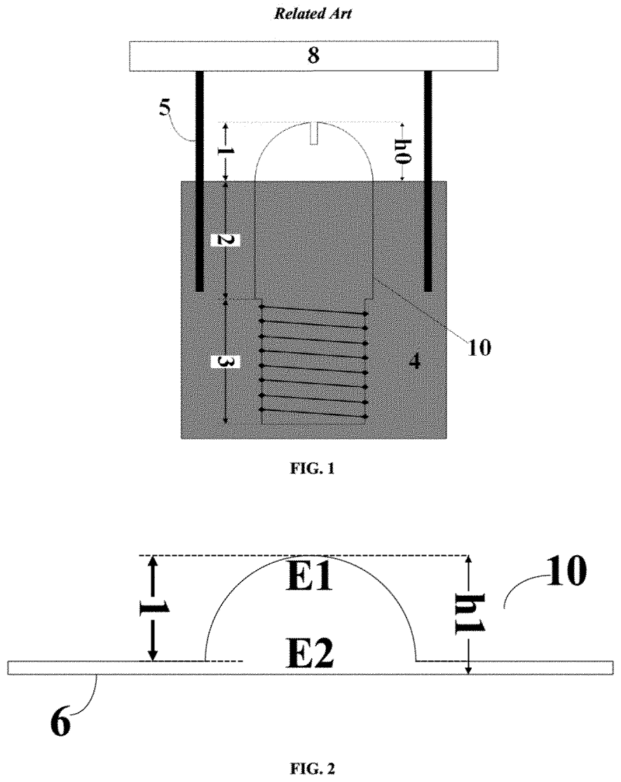

FIG. 1 is a schematic diagram illustrating the structure of a conventional substrate processing apparatus. Referring to FIG. 1, the conventional substrate processing apparatus (e.g., a hot plate baking apparatus) includes a hot plate 4 for controlling the temperature of the substrate processing apparatus, a plurality of lift pins 5 for raising and lowering the substrate 8 when the substrate 8 is loaded on the plurality of lift pins 5, and a plurality of proximity pins 10 inserted in the hot plate 4. The plurality of lift pins 5 are ascendable and descendible in the hot plate 4. When the plurality of lift pins 5 are descended into the hot plate 4, the substrate 8 is mounted on the plurality of proximity pins 10, which support the substrate 8 in the substrate processing apparatus. Each of the plurality of proximity pins 10 includes a pin head part 1, a body part 2, and a threaded pin part 3. The body part 2 connects the pin head part 1 and the threaded pin part 3. Each of the plurality of proximity pins 10 is inserted in to the hot plate 4, and is threadedly secured to the hot plate through the threaded pin part 3. The pin head part 1 is exposed above the hot plate 4 to prevent direct contact between the substrate 8 and the hot plate 4. As shown in FIG. 1, the pin head part 1 has a height h0. In the conventional substrate processing apparatus, the height h0 is typically set to be approximately 0.3 mm.

In the conventional substrate processing apparatus, the plurality of proximity pins 10 are prone to wear and tear due to frequent contact with the substrate 8, resulting in a reduced height. Moreover, the substrate 8 is prone to bend toward the hot plate 4 due to its own weight. When the height of the plurality of proximity pins 10 is reduced, often the substrate 8 is in contact with the hot plate 4 when loaded onto the plurality of proximity pins 10, especially in areas where the substrate 8 is bent toward to the hot plate 4. The issue becomes particularly problematic when the distribution density of the plurality of proximity pins 10 in the hot plate 4 is relatively low, or when the substrate 8 is one that is relatively heavy or relatively flexible.

When a contact between the substrate 8 and the hot plate 4 occurs during the substrate processing (e.g., baking), the substrate 8 is prone to defects such as cracks in the contacting areas when the plurality of lift pins 5 raise the substrate 8 out of the substrate processing apparatus. These issues severely increase the manufacturing costs, decrease fabrication capacity, resulting in waste and inefficiencies.

Accordingly, the present disclosure provides, inter alia, a proximity pin, a substrate processing apparatus, and a method of processing a substrate in a substrate processing apparatus that substantially obviate one or more of the problems due to limitations and disadvantages of the related art. Using the present proximity pin, the substrate processing apparatus and the method thereof, the contact between the substrate and the hot plate during the baking process can be completely avoided.

In one aspect, the present disclosure provides a proximity pin for supporting a substrate in a substrate processing apparatus. In some embodiments, the proximity pin includes a pin head part configured to support the substrate in the substrate processing apparatus; and a support pad part connected to the pin head part. Optionally, the pin head part includes a first end and a second end opposite to the first end. The first end is configured to be in contact with the substrate placed on the proximity pin. The support pad part is connected to the pin head part at the second end of the pin head part, and has a diameter larger than a maximum diameter of the pin head part.

FIG. 2 is a schematic diagram illustrating the structure of a proximity pin in some embodiments according to the present disclosure. Referring to FIG. 2, the proximity pin 10 includes a pin head part 1 configured to support a substrate in the substrate processing apparatus; and a support pad part 6 connected to the pin head part 1. The pin head part 1 includes a first end E1 and a second end E2 opposite to the first end E1. The first end E1 is configured to be in contact with the substrate placed on the proximity pin 10. The support pad part 6 is connected to the pin head part 1 at the second end E2 of the pin head part 1. The pin head part 1 and the support pad part 6 have a combined height h1. Optionally, the combined height h1 is greater than 0.30 mm, e.g., substantially equal to or greater than 0.40 mm, substantially equal to or greater than 0.45 mm, substantially equal to or greater than 0.50 mm.

The support pad part 6 has a diameter larger than a maximum diameter of the pin head part 1. For example, the support pad part 6 protrudes outwards relative to the pin head part. IG. 3 is a plan view of the proximity pin in FIG. 2. Referring to IG. 3, the maximum diameter of the pin head part 1 is d1, and the support pad part 6 has a diameter d2. Optionally, a ratio of the diameter d2 of the support pad part 6 to the maximum diameter d1 of the pin head part 1 is in a range of approximately 1.1:1.0 to approximately 10:1.0, e.g., approximately 1.1:1.0 to approximately 1.5:1.0, approximately 1.5:1.0 to approximately 2.0:1.0, approximately 2.0:1.0 to approximately 2.5:1.0, approximately 2.5:1.0 to approximately 3.0:1.0, approximately 3.0:1.0 to approximately 3.5:1.0, approximately 3.5:1.0 to approximately 4.0:1.0, approximately 5.0:1.0 to approximately 7.5:1.0, and approximately 7.5:1.0 to approximately 10:1.0.

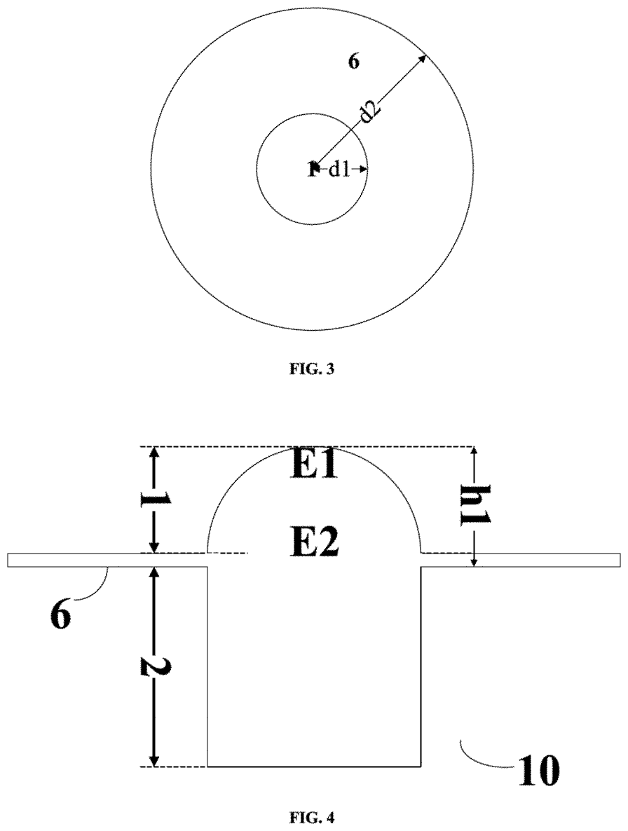

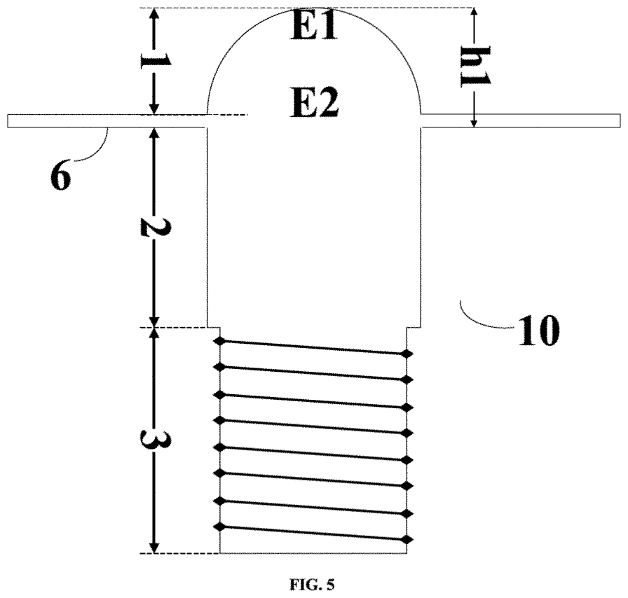

FIG. 4 is a schematic diagram illustrating the structure of a proximity pin in some embodiments according to the present disclosure. Referring to FIG. 4, the proximity pin in some embodiments includes a pin head pan 1 configured to support a substrate in the substrate processing apparatus; a support pad part 6 connected to the pin head part 1; and a body part 2 connected to the support pad part 6. The body part 2 is configured to be inserted into a hole in a hot plate in the substrate processing apparatus, and may be secured to the hot plate by various appropriate methods, e.g., by adhesive, magnetic force, etc. Optionally, a ratio of the diameter of the support pad part 6 to the maximum diameter of the body part 2 is in a range of approximately 1.1:1.0 to approximately 10:1.0, e.g., approximately 1.1:1.0 to approximately 2.0:1.0, approximately 2.0:1.0 to approximately 3.0:1.0, approximately 3.0:1.0 to approximately 5.0:1.0, approximately 5.0:1.0 to approximately 10:1.0.

Optionally, a ratio of the maximum diameter of the pin head part 1 to the maximum diameter of the body part 2 is in a range of approximately 0.5:1.0 to approximately 2.0:1.0, e.g., approximately 0.5:1.0 to approximately 1.5:1.0, approximately 0.75:1.0 to approximately 1.5:1.0, approximately 0.9:1.0 to approximately 1.2:1.0, approximately 1.0:1.0 to approximately 1.1:1.0, and approximately 1.0:1.0 to approximately 1.05:1.0.

FIG. 5 is a schematic diagram illustrating the structure of a proximity pin in some embodiments according to the present disclosure. Referring to FIG. 5, the proximity pin in some embodiments includes a pin head part 1 configured to support a substrate in the substrate processing apparatus; a support pad part 6 connected to the pin head part 1; a threaded pin part 3 configured to threadedly secure the proximity pin 10 to the hot plate in the substrate processing apparatus; and a body part 2 connecting the support pad part 6 and the threaded pin part 3. The support pad part 6 has a diameter larger than a maximum diameter of any other parts of the proximity pin 10. Optionally, a ratio of the diameter of the support pad part 6 to the maximum diameter of any other parts of the proximity pin 10 is in a range of approximately 1.1:1.0 to approximately 10:1.0, e.g., approximately 1.1:1.0 to approximately 2.0:1.0, approximately 2.0:1.0 to approximately 3.0:1.0, approximately 3.0:1.0 to approximately 5.0:1.0, approximately 5.0:1.0 to approximately 10:1.0.

Optionally, a ratio of the maximum diameter of the pin head part 1 to the maximum diameter of any parts of the proximity pin 10 other than the support pad part 6 and the pin head part 1 is in a range of approximately 0.5:1.0 to approximately 2.0:1.0, e.g., approximately 0.5:1.0 to approximately 1.5:1.0, approximately 0.75:1.0 to approximately 1.5:1.0, approximately 0.9:1.0 to approximately 1.2:1.0, approximately 1.0:1.0 to approximately 1.1:1.0, and approximately 1.0:1.0 to approximately 1.05:1.0.

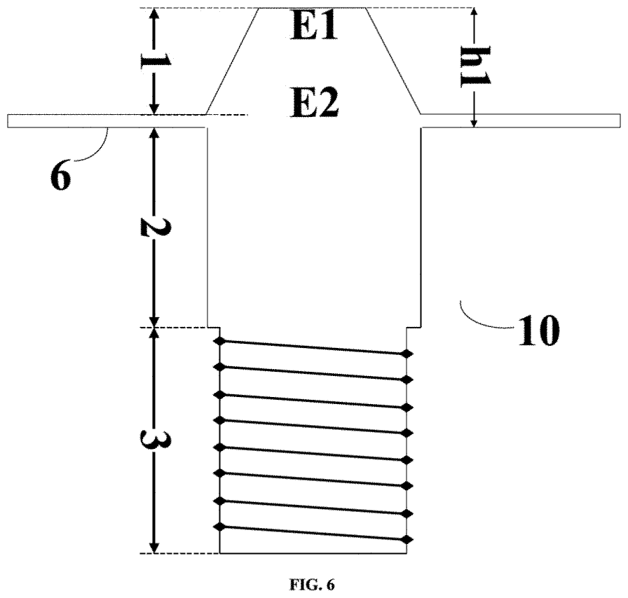

The pin head part 1 may have various appropriate shapes. The proximity pin 10 in FIGS. 2, 4, and S has a partial spherical shape. Optionally, the proximity pin 10 has a substantially spherical shape. Optionally, the proximity pin 10 has a substantially cubic shape. Optionally, the proximity pin 10 has a substantially cylindrical shape. Optionally, the proximity pin 10 has a substantially rectangular pyramid shape. Optionally, the proximity pin 10 has a shape that is narrow on top (e.g., the first end E1) and wide on bottom (e.g., the second end E2). FIG. 6 is a schematic diagram illustrating the structure of a proximity pin in some embodiments according to the present disclosure. Referring to FIG. 6, the proximity pin 10 in some embodiments has a truncated pyramid shape.

Optionally, the proximity pin 10 has an integral structure; all parts of the proximity pin 10 form an integral structure.

Any appropriate material may be used for making the proximity pin 10. Optionally, the proximity pin 10 is made of a high-temperature resistant material. Optionally, the proximity pin 10 is made of an inorganic material, e.g., a metal. Optionally, the proximity pin 10 is made of an organic material, e.g., polyether ether ketone, polyimide, and polyamide-imide.

In another aspect, the present disclosure provides a substrate processing apparatus having a plurality of proximity pins described above. In some embodiments, the substrate processing apparatus includes a hot plate and at least one of the proximity pin described above. The present disclosure provides two types of proximity pins, e.g., a first proximity pin and a second proximity pin. The first proximity pin includes at least a body part that is configured to be engaged with a hole in the hot plate. The second proximity pin does not include a body part to be inserted into a hole of the hot plate. Thus, the second proximity pin can be moved and secured to any desired position on the hot plate whereas the first proximity pin is limited to a position where the hot plate has a hole for receiving at least the body part of the first proximity pin. The present substrate processing apparatus includes one or both types of proximity pins. Optionally, the substrate processing apparatus includes only one or more first proximity pins but not the second proximity pin. Optionally, the substrate processing apparatus includes only one or more second proximity pins but not the first proximity pin. Optionally, the substrate processing apparatus includes one or more first proximity pins and one or more second proximity pins.

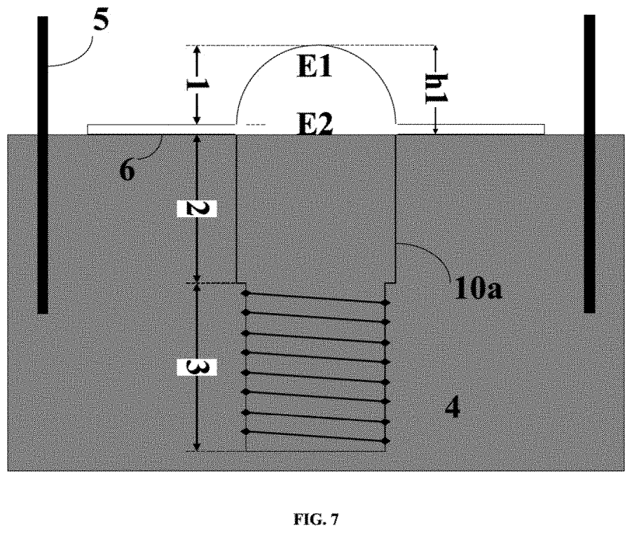

FIG. 7 is a schematic diagram illustrating the structure of a substrate processing apparatus in some embodiments according to the present disclosure. Referring to FIG. 7, the substrate processing apparatus in some embodiments includes a hot plate 4 for controlling the temperature of the substrate processing apparatus, a plurality of lift pins 5 for raising and lowering a substrate when the substrate is loaded on the plurality of lift pins 5, and a first proximity pin 10a inserted in the hot plate 4. As shown in FIG. 7, the first proximity pin 10a includes a pin head part 1 configured to support a substrate in the substrate processing apparatus; a support pad part 6 connected to the pin head part 1; a threaded pin part 3 configured to threadedly secure the proximity pin 10 to the hot plate in the substrate processing apparatus; and a body part 2 connecting the support pad part 6 and the threaded pin part 3. The pin head part 1 is exposed above the hot plate 4 to prevent direct contact between the substrate 8 and the hot plate 4. The support pad part 6 is received on a surface of the hot plate 4. The body part 2 and the threaded pin part 3 are inserted into the hot plate 4. The hot plate 4 includes a threaded hole (complementary to the threaded pin part 3 in FIG. 7) for receiving the threaded pin part 3 of the first proximity pin 10a. The pin head part 1 and the support pad part 6 have a combined height h1. Optionally, the combined height h1 is greater than 0.30 mm, e.g., substantially equal to or greater than 0.40 mm, substantially equal to or greater than 0.45 mm, substantially equal to or greater than 0.50 mm.

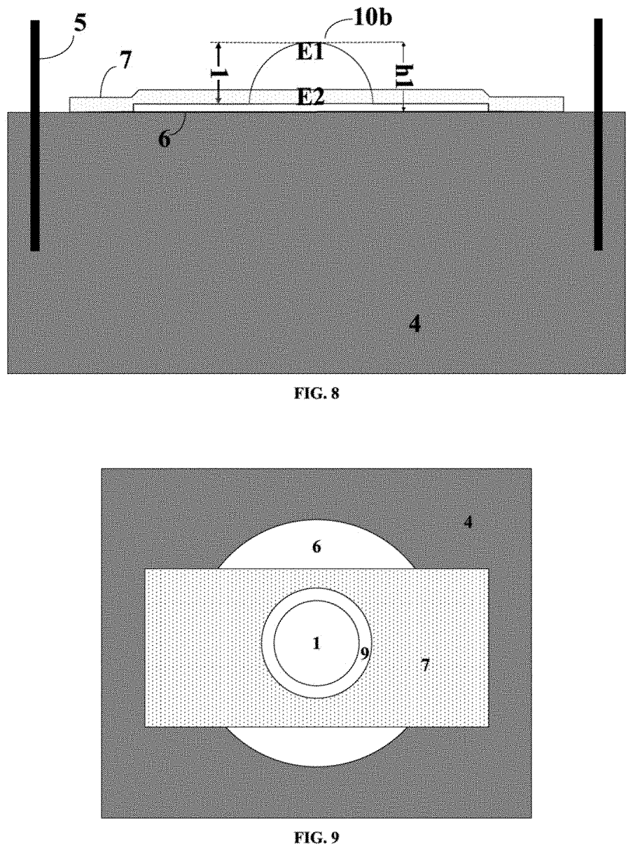

FIG. 8 is a schematic diagram illustrating the structure of a substrate processing apparatus in some embodiments according to the present disclosure. FIG. 9 is a plan view of the substrate processing apparatus in FIG. 8. Referring to FIG. 8 and FIG. 9, the substrate processing apparatus in some embodiments includes a hot plate 4 for controlling the temperature of the substrate processing apparatus, a plurality of lift pins 5 for raising and lowering a substrate when the substrate is loaded on the plurality of lift pins 5, and a second proximity pin 10b placed on a surface of the hot plate 4, e.g., not inserted into the hot plate 4. As shown in FIG. 8 and FIG. 9, the second proximity pin 10b includes a pin head part 1 configured to support a substrate in the substrate processing apparatus and a support pad part 6 connected to the pin head part 1. The pin head part 1 is exposed above the hot plate 4 to prevent direct contact between the substrate 8 and the hot plate 4. The support pad part 6 is received on a surface of the hot plate 4. The pin head part 1 and the support pad part 6 have a combined height h1. Optionally, the combined height h1 is greater than 0.30 mm, e.g., substantially equal to or greater than 0.40 mm, substantially equal to or greater than 0.45 mm, substantially equal to or greater than 0.50 mm.

Because the second proximity pin 10b is not inserted into a hole in the hot plate 4, it can be moved and secured to any position on the hot plate 4 as desired. The substrate processing apparatus may include any appropriate number of the second proximity pins 10b. For example, additional second proximity pins 10b may be placed and secured to the surface of the hot plate 4 in order to increase the distribution density of proximity pins on the hot plate 4, when the substrate to be processed is more prone to be in contact with the hot plate 4. In one example, when the substrate is not prone to be in contact with the hot plate 4, a smaller number (or none) of second proximity pins 10b may be used in the substrate processing apparatus.

As shown in FIG. 8 and FIG. 9, in some embodiments, the second proximity pin 10b is secured on the hot plate 4 through an adhesive tape 7 adhering the support pad part 6 and the hot plate 4 together. The adhesive tape 7 may have any appropriate shape. In one example, the adhesive tape 7 adheres two sides of the support pad part 6 to the hot plate 4. As shown in FIG. 9, in some embodiments, the adhesive tape 7 includes an opening 9 in the middle of the adhesive tape 7. The pin head part 1 of the second proximity pin 10b extends through the opening 9, e.g., is not covered by the adhesive tape 7. Optionally, the adhesive tape 7 is a high temperature resistant adhesive tape.

In some embodiments, the substrate processing apparatus includes a plurality of first proximity pins and a plurality of second proximity pins. For example, each of the plurality of first proximity pins includes a body part configured to be inserted into the hot plate 4 of the substrate processing apparatus (e.g., the first proximity pin 10a as shown in FIG. 7), and each of the plurality of second proximity pins are configured to be secured to the hot plate 4 by an adhesive tape 7 (e.g., the second proximity pin 10b as shown in FIG. 8 and FIG. 9). The hot plate 4 includes a plurality of holes, each of which is configured to receive one of the plurality of first proximity pins. Each of the plurality of first proximity pins is secured in one of the plurality of holes in the hot plate. Each of the plurality of second proximity pins is secured on the hot plate through an adhesive tape adhering the support pad part and the hot plate together.

Optionally, each of the plurality of first proximity pins further includes a threaded pin part and a body part connecting the support pad part and the threaded pin part. Each of the plurality of holes is a threaded hole configured to receive the threaded pin part of one of the plurality of first proximity pins. Each of the plurality of first proximity pins is threadedly secured in the hot plate through the threaded pin part.

Optionally, the pin head part and the support pad part of each of the plurality of first proximity pins have a first combined height. Optionally, the pin head part and the support pad part of each of the plurality of second proximity pins have a second combined height. Optionally, the first combined height is substantially the same as the second combined height. Optionally, each of the first combined height and the second combined height is greater than 0.30 mm, e.g., substantially equal to or greater than 0.40 mm, substantially equal to or greater than 0.45 mm, substantially equal to or greater than 0.50 mm.

In another aspect, the present disclosure provides a method of processing a substrate in a substrate processing apparatus described herein. In some embodiments, the method includes placing the substrate on at least one of the proximity pin described herein; and baking the substrate in the substrate processing apparatus. Optionally, the at least one of the proximity pin include a plurality of first proximity pins and a plurality of second proximity pins described above.

In some embodiments, prior to placing the substrate on at least one of the proximity pin, the method further includes placing the plurality of second proximity pins on the hot plate; and securing each of the plurality of second proximity pins onto the hot plate using an adhesive tape adhering the support pad part and the hot plate together.

In some embodiments, the method further includes changing a position of at least one of the plurality of second proximity pins on the hot plate. Optionally, the step of changing the position of at least one of the plurality of second proximity pins on the hot plate includes removing the adhesive tape from the at least one of the plurality of second proximity pins; moving the at least one of the plurality of second proximity pins to a new position on the hot plate; and securing the at least one of the plurality of second proximity pins at the new position using the adhesive tape.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A proximity pin for supporting a substrate in a substrate processing apparatus, comprising:
a pin head part configured to support the substrate in the substrate processing apparatus, and comprising a first end and a second end opposite to the first end, the first end being configured to be in contact with the substrate placed on the proximity pin; and
a support pad part connected to the pin head part at the second end of the pin head part, and has a diameter larger than a maximum diameter of the pin head part.

2. The proximity pin of claim 1, further comprising:
a threaded pin part configured to threadedly secure the proximity pin to the hot plate in the substrate processing apparatus; and
a body part connecting the support pad part and the threaded pin part.

3. The proximity pin of claim 1, wherein the first end of the pin head part has a first diameter smaller than a second diameter of the second end of the pin head part.

4. The proximity pin of claim 1, wherein the pin head part and the support pad part have a combined height greater than approximately 0.4 mm.

5. The proximity pin of claim 1, wherein a ratio of the diameter of the support pad part to a maximum diameter of any other parts of the proximity pin is in a range of approximately 1.1:1.0 to approximately 10:1.0; and
a ratio of a maximum diameter of the pin head part to the maximum diameter of any parts of the proximity pin other than the support pad part and the pin head part is in a range of approximately 0.5:1.0 to approximately 1.05:1.0.

6. A substrate processing apparatus, comprising:
a hot plate; and
at least one of the proximity pin of claim 1.

7. The substrate processing apparatus of claim 6, wherein the first end of the pin head part has a first diameter smaller than a second diameter of the second end of the pin head part.

8. The substrate processing apparatus of claim 6, wherein the pin head part and the support pad part have a total height greater than approximately 0.4 mm.

9. The substrate processing apparatus of claim 6, wherein the at least one of the proximity pin comprise a first proximity pin; and
the hot plate comprises a hole configured to receive the first proximity pin in the hole.

10. The substrate processing apparatus of claim 9, wherein the first proximity pin further comprises a threaded pin part and a body part connecting the support pad part and the threaded pin part;
the hole in the hot plate is a threaded hole configured to receive the threaded pin part of the first proximity pin; and
the first proximity pin is threadedly secured in the hot plate through the threaded pin part.

11. The substrate processing apparatus of claim 6, wherein the at least one of the proximity pin comprise a second proximity pin;
the second proximity pin is secured on the hot plate through an adhesive tape adhering the support pad part and the hot plate together.

12. The substrate processing apparatus of claim 11, wherein the adhesive tape comprises an opening; and
the pin head part extends through the opening.

13. The substrate processing apparatus of claim 11, wherein the adhesive tape is a high temperature resistant adhesive tape.

14. The substrate processing apparatus of claim 6, wherein the at least one of the proximity pin comprise a plurality of first proximity pins and a plurality of second proximity pins;
the hot plate comprises a plurality of holes, each of which is configured to receive one of the plurality of first proximity pins;
each of the plurality of first proximity pins is secured in one of the plurality of holes in the hot plate; and
each of the plurality of second proximity pins is secured on the hot plate through an adhesive tape adhering the support pad part and the hot plate together.

15. The substrate processing apparatus of claim 14, wherein the pin head part and the support pad part of each of the plurality of first proximity pins have a first combined height;
the pin head part and the support pad part of each of the plurality of second proximity pins have a second combined height; and
the first combined height is substantially the same as the second combined height.

16. The substrate processing apparatus of claim 15, wherein each of the first combined height and the second combined height is greater than approximately 0.4 mm.

17. The substrate processing apparatus of claim 14, wherein each of the plurality of first proximity pins further comprises a threaded pin part and a body part connecting the support pad part and the threaded pin part;
each of the plurality of holes is a threaded hole configured to receive the threaded pin part of one of the plurality of first proximity pins; and
each of the plurality of first proximity pins is threadedly secured in the hot plate through the threaded pin part.

18. A method of processing a substrate in a substrate processing apparatus of claim 6, comprising:
placing the substrate on at least one of the proximity pin; and
baking the substrate in the substrate processing apparatus.

19. The method of claim 18, wherein the at least one of the proximity pin comprise a plurality of first proximity pins and a plurality of second proximity pins;
each of the plurality of first proximity pins comprises the pin head part, the support pad part, a threaded pin part, and a body part connecting the support pad part and the threaded pin part;
each of the plurality of first proximity pins is threadedly secured in the hot plate through the threaded pin part; and
each of the plurality of second proximity pins comprises the pin head part and the support pad part; and
prior to placing the substrate on at least one of the proximity pin, the method further comprising:
placing the plurality of second proximity pins on the hot plate; and
securing each of the plurality of second proximity pins onto the hot plate using an adhesive tape adhering the support pad part and the hot plate together.

20. The method of claim 19, further comprising changing a position of at least one of the plurality of second proximity pins on the hot plate by:
removing the adhesive tape from the at least one of the plurality of second proximity pins;
moving the at least one of the plurality of second proximity pins to a new position on the hot plate; and
securing the at least one of the plurality of second proximity pins at the new position using the adhesive tape.
